(19) United States
(12) Patent Application Publication
(10) Pub. No.: US 2019/0148150 A1
(43) Pub. Date: May 16, 2019

(54) METHODS FOR FORMING CAPPING PROTECTION FOR AN INTERCONNECTION STRUCTURE

(71) Applicant: Applied Materials, Inc., Santa Clara, CA (US)

(72) Inventors: Joung Joo LEE, San Jose, CA (US); Feng CHEN, San Jose, CA (US); Zhiyuan WU, San Jose, CA (US); Atashi BASU, Menlo Park, CA (US); Mehul B. NAIK, San Jose, CA (US); Yufei HU, Santa Clara, CA (US)

(21) Appl. No.: 16/172,786

(22) Filed: Oct. 27, 2018

Related U.S. Application Data
(60) Provisional application No. 62/585,368, filed on Nov. 13, 2017.

(51) Int. Cl. H01L 21/28; H01L 21/02; H01L 21/768; H01L 21/285; H01L 23/532; H01L 23/528

(52) U.S. Cl. CPC H01L 21/28097; H01L 21/02362; H01L 21/28247; H01L 21/76841; H01L 23/5329; H01L 21/76834; H01L 23/53233; H01L 23/528; H01L 23/53238; H01L 21/28562

(57) ABSTRACT

Methods for forming a capping protection structure on a metal line layer formed in an insulating material in an interconnection structure are provided. In one embodiment, a method for forming capping protection on a metal line in an interconnection structure for semiconductor devices includes selectively forming a metal silicide layer on a metal line bounded by a dielectric bulk insulating layer in a back end interconnection structure formed on a substrate in a processing chamber; and forming a dielectric layer on the metal silicide layer.

### CROSS-REFERENCE TO RELATED APPLICATIONS

This application claims benefit of U.S. Patent Application No. 62/586,368, filed on Nov. 13, 2017, the contents of which are herein incorporated by reference.

### BACKGROUND OF THE INVENTION

### Field of the Invention

Embodiments of the present invention generally relate to methods for forming passivation protection for an interconnection structure. More particularly, embodiments of the present invention generally relate to methods for forming passivation protection for an interconnection structure for semiconductor devices to prevent excess oxidation.

### Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate is important to VLSI and ULSI success and to the continued effort to increase circuit density and quality of individual substrates and die.

A patterned mask, such as a photoresist layer, is commonly used during etching structures, such as gate structure, shallow trench isolation (STI), bit lines and the like, or back end dual damascene structure on a substrate. The patterned mask is conventionally fabricated by using a lithographic process to optically transfer a pattern having the desired critical dimensions to a layer of photoresist. The photoresist layer is then developed to remove undesired portions of the photoresist, thereby creating openings in the remaining photoresist.

As the dimensions of the integrated circuit components are reduced (e.g., to deep sub-micron dimensions), the materials used to fabricate such components must be carefully selected in order to obtain satisfactory levels of electrical performance. For example, when the distance between adjacent metal interconnects and/or the thickness of the dielectric bulk insulating material that isolates interconnects having sub-micron dimensions, the potential for capacitive coupling occurs between the metal interconnects is high. Capacitive coupling between adjacent metal interconnects may cause cross talk and/or resistance-capacitance (RC) delay which degrades the overall performance of the integrated circuit and may render the circuit inoperable. In order to minimize capacitive coupling between adjacent metal interconnects, low dielectric constant bulk insulating materials (e.g., dielectric constants less than about 4.0) are needed. Examples of low dielectric constant bulk insulating materials include silicon dioxide (SiO₂), silicate glass, fluorosilicate glass (FSG), and carbon doped silicon oxide (SiOC), among others.

During the semiconductor manufacturing process, after a metal CMP process, the underlying upper surface of the metal line formed from the dielectric bulk insulating materials is exposed to air. Prior to the subsequent metallization process to form interconnection on the exposed metal, the substrate may be transferred among different vacuum environments to perform a different processing steps. During transfer, the substrate may have to reside outside the process chamber or controlled environment for a period of time called the queue time (Q-time). During the Q-time, the substrate is exposed to ambient environmental conditions that include oxygen and water at atmospheric pressure and room temperature. As a result, the substrate subjected to oxidizing conditions in the ambient environment may accumulate native oxides or contaminants on the metal surface prior to the subsequent metallization process or interconnection fabrication process.

Furthermore, poor adhesion at the interface, when interface native oxides are formed, may also result in undesired high contact resistance, thereby resulting in undesirably poor electrical properties of the device. In addition, poor nucleation of the metal elements in the back end interconnection may impact not only the electrical performance of the devices, but also on the integration of the conductive contact material subsequently formed thereon.

Recently, a metal containing passivation layer is utilized to cover the exposed surface of a metal line formed in interconnects from the dielectric bulk insulating materials. The metal containing passivation layer may minimize exposure of the metal line from the interconnect material to atmosphere/air so as to prevent damage to the semiconductor device. The metal containing passivation layer may also prevent a barrier/blocking functions to prevent the underlying conductive metal elements undesirably diffused to the nearby insulating materials. Furthermore, materials selected to fabricate the metal containing passivation layer are often required to provide certain desired degree of conductivity as well as high moisture/contamination resistance and barrier functions so as to serve as a good passivation protection at the interface as well as maintaining low resistivity at the interconnection interface. By utilizing this metal containing passivation layer formed on the metal line, exposure to the air/atmosphere may be minimized and the interface diffusion prevention may be obtained. However, in some cases, inadequate selection or utilization of the metal containing passivation layer may result in insufficient moisture or diffusion resistance, or film degradation during the subsequent plasma process, thereby eventually leading to device failure.

Thus, there is a need for improved methods to form an interconnection passivation protection structure with good interface quality control for metal exposure with minimum substrate oxidation.

### SUMMARY

Methods for forming a capping protection structure on a metal line layer formed in an insulating material in an interconnection structure are provided. In one embodiment, a method for forming capping protection on a metal line in an interconnection structure for semiconductor devices includes selectively forming a metal silicide layer on a metal line bounded by a dielectric bulk insulating layer in a back end interconnection structure formed on a substrate in a processing chamber; and forming a dielectric layer on the metal silicide layer.

In another embodiment, a semiconductor back end interconnection structure includes a copper metal line bounded by a dielectric bulk insulating layer in a back end interconnection structure formed on a substrate, a metal silicide layer disposed on the copper metal layer, and a dielectric layer disposed on the metal silicide layer.

In yet another embodiment, a method for forming capping protection on a metal line in an interconnection structure for semiconductor devices includes supplying a silicon containing gas to a metal line bounded by a dielectric bulk insulating layer in a back end interconnection structure formed on a substrate, forming a metal silicide layer on the metal layer, supplying a cobalt containing gas to the metal line formed on the substrate to form a capping layer on the metal silicide layer, and forming a dielectric layer on the capping layer.

### BRIEF DESCRIPTION OF THE DRAWINGS

So that the manner in which the above recited features of the present invention can be understood in detail, a more particular description of the invention, briefly summarized above, can be had by reference to embodiments, some of which are illustrated in the appended drawings. It is to be noted, however, that the appended drawings illustrate only typical embodiments of this invention and are therefore not to be considered limiting of its scope, for the invention can admit to other equally effective embodiments.

FIG. 1 depict an apparatus that may be utilized to perform an atomic layer deposition (ALD) process in accordance with one embodiment of the present disclosure;

FIG. 2 depicts an apparatus may be utilized to perform an chemical vapor deposition (CVD) process in accordance with one embodiment of the present disclosure;

FIG. 3 depicts a flow diagram of an example of a method for selectively forming a material on certain locations on a substrate;

FIGS. 4A-4G depict one embodiment of a sequence for forming a material selectively on certain locations on the substrate during the manufacturing process according to the process depicted in FIG. 3.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Methods for forming a capping protection structure on a metal line layer formed in an insulating material in a semiconductor device are provided. The passivation protection structure formed on the metal line may efficiently protect the metal line from diffusing to the nearly insulating layer or other types of the layers, thereby substantially eliminating the likelihood of contamination, electron migration, current leak, and maintaining a good interface control. In one embodiment, the capping protection structure may include at least one layer fabricated from a metal containing layer. The capping protection structure may be a single layer, stack layer with multiple layers, a single or multiple layer stacks comprising metal silicide. In one embodiment, such metal silicide layer may be a Co silicide layer. By utilizing a proper capping protection structure formed on a metal line, the likelihood of electron migration or the metal line eruption/diffusion may be eliminated, thus increasing manufacturing flexibility without degradation of device performance.

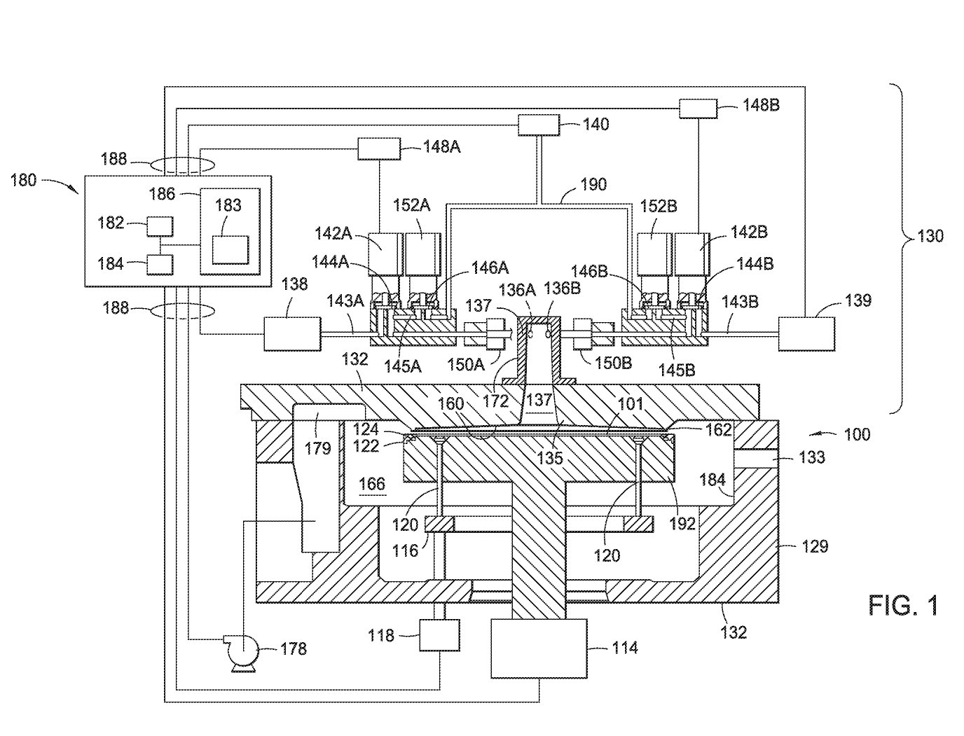

FIG. 1 is a schematic cross-sectional view of one embodiment of an atomic layer deposition (ALD) processing chamber 100. The ALD processing chamber 100 includes a gas delivery apparatus 130 adapted for cyclic deposition, such as ALD or chemical vapor deposition (CVD). The terms ALD and CVD as used herein refer to the sequential introduction of reactants to deposit a thin layer over a substrate structure. The sequential introduction of reactants may be repeated to deposit a plurality of thin layers to form a conformal layer to a desired thickness. The chamber 100 may also be adapted for other deposition techniques along with lithography process.

The chamber 100 comprises a chamber body 129 having a bottom 132. A slit valve tunnel 133 formed through the chamber body 129 provides access for a robot (not shown) to deliver and retrieve a substrate 101, such as a 200 mm, 300 mm or 450 mm semiconductor substrate or a glass substrate, from the chamber 100.

A substrate support 192 is disposed in the chamber 100 and supports the substrate 101 during processing. The substrate support 192 is mounted to a lift 114 to raise and lower the substrate support 192 and the substrate 101 disposed thereon. A lift plate 116 is connected to a lift plate actuator 118 that controls the elevation of the lift plate 116. The lift plate 116 may be raised and lowered to raise and lower pins 120 movably disposed through the substrate support 192. The pins 120 are utilized to raise and lower the substrate 101 over the surface of the substrate support 192. The substrate support 192 may include a vacuum chuck, an electrostatic chuck, or a clamp ring for securing the substrate 101 to the surface of the substrate support 192 during processing.

The substrate support 192 may be heated to heat the substrate 101 disposed thereon. For example, the substrate support 192 may be heated using an embedded heating element, such as a resistive heater, or may be heated using radiant heat, such as heating lamps disposed above the substrate support 192. A purge ring 122 may be disposed on the substrate support 192 to define a purge channel 124 which provides a purge gas to a peripheral portion of the substrate 101 to prevent deposition thereon.

A gas delivery apparatus 130 is disposed at an upper portion of the chamber body 129 to provide a gas, such as a process gas and/or a purge gas, to the chamber 100. A pumping system 178 is in communication with a pumping channel 179 to evacuate any desired gases from the chamber 100 and to help maintain a desired pressure or a desired pressure range inside a pumping zone 166 of the chamber 100.

In one embodiment, the gas delivery apparatus 130 comprises a chamber lid 132. The chamber lid 132 includes an expanding channel 137 extending from a central portion of the chamber lid 132 and a bottom surface 160 extending from the expanding channel 137 to a peripheral portion of the chamber lid 132. The bottom surface 160 is sized and shaped to substantially cover the substrate 101 disposed on the substrate support 192. The chamber lid 132 may have a choke 162 at a peripheral portion of the chamber lid 132 adjacent the periphery of the substrate 101. The cap portion 172 includes a portion of the expanding channel 137 and gas inlets 136A, 136B. The expanding channel 137 has gas inlets 136A, 136B to provide gas flows from two similar valves 142A, 142B. The gas flows from the valves 142A, 142B may be provided together and/or separately.

In one configuration, valve 142A and valve 142B are coupled to separate reactant gas sources, but are coupled to the same purge gas source. For example, valve 142A is coupled to a reactant gas source 138 and valve 142B is coupled to reactant gas source 139, which both valves 142A, 142B are coupled to purge a gas source 140. Each valve 142A, 142B includes a delivery line 143A, 143B having a valve seat assembly 144A, 144B and includes a purge line 145A, 145B having a valve seat assembly 146A, 146B. The delivery line 143A, 143B is in communication with the reactant gas source 138, 139 and is in communication with the gas inlet 137A, 137B of the expanding channel 190. The valve seat assembly 144A, 144B of the delivery line 143A, 143B controls the flow of the reactant gas from the reactant gas source 138, 139 to the expanding channel 190. The purge line 145A, 145B is in communication with the purge gas source 140 and intersects the delivery line 143A, 143B downstream of the valve seat assembly 144A, 144B of the delivery line 143A, 143B. The valve seat assembly 146A, 146B of the purge line 145A, 145B controls the flow of the purge gas from the purge gas source 140 to the delivery line 143A, 143B. If a carrier gas is used to deliver reactant gases from the reactant gas source 138, 139, the same gas may be used as a carrier gas and a purge gas (i.e., an argon gas may be used as both a carrier gas and a purge gas).

Each valve 142A, 142B may be a zero dead volume valve to enable flushing of a reactant gas from the delivery line 143A, 143B when the valve seat assembly 144A, 144B of the valve is closed. For example, the purge line 145A, 145B may be positioned adjacent the valve seat assembly 144A, 144B of the delivery line 143A, 143B. When the valve seat assembly 144A, 144B is closed, the purge line 145A, 145B may provide a purge gas to flush the delivery line 143A, 143B. In the embodiment shown, the purge line 145A, 145B is positioned as slightly spaced from the valve seat assembly 144A, 144B of the delivery line 143A, 143B so that a purge gas is not directly delivered into the valve seat assembly 144A, 144B when open. A zero dead volume valve as used herein is defined as a valve which has negligible dead volume (i.e., not necessary zero dead volume.) Each valve 142A, 142B may be adapted to provide a combined gas flow and/or separate gas flow of the reactant gas from the sources 138, 139 and the purge gas from the source 140. The pulses of the purge gas may be provided by opening and closing a diaphragm of the valve seat assembly 146A of the purge line 145A. The pulses of the reactant gas from the reactant gas source 138 may be provided by opening and closing the valve seat assembly 144A of the delivery line 143A.

A control unit 180 may be coupled to the chamber 100 to control processing conditions. The control unit 180 comprises a central processing unit (CPU) 182, support circuitry 184, and memory 186 containing associated control software 183. The control unit 180 may be one of any form of general purpose computer processors that can be used in an industrial setting for controlling various chambers and sub-processors. The CPU 182 may use any suitable memory 186, such as random access memory, read only memory, floppy disk drive, compact disc drive, hard disk, or any other form of digital storage, local or remote. Various support circuits may be coupled to the CPU 182 for supporting the chamber 100. The control unit 180 may be coupled to another controller that is located adjacent individual chamber components, such as the programmable logic controllers 148A, 148B of the valves 142A, 142B. Bi-directional communications between the control unit 180 and various other components of the chamber 100 are handled through numerous signal cables collectively referred to as signal buses 188, some of which are illustrated in FIG. 1. In addition to the control of process gases and purge gases from gas sources 138, 139, 140 and from the programmable logic controllers 148A, 148B of the valves 142A, 142B, the control unit 180 may be configured to be responsible for automated control of other activities used in substrate processing, such as substrate transport, temperature control, chamber evacuation, among other activities, some of which are described elsewhere herein.

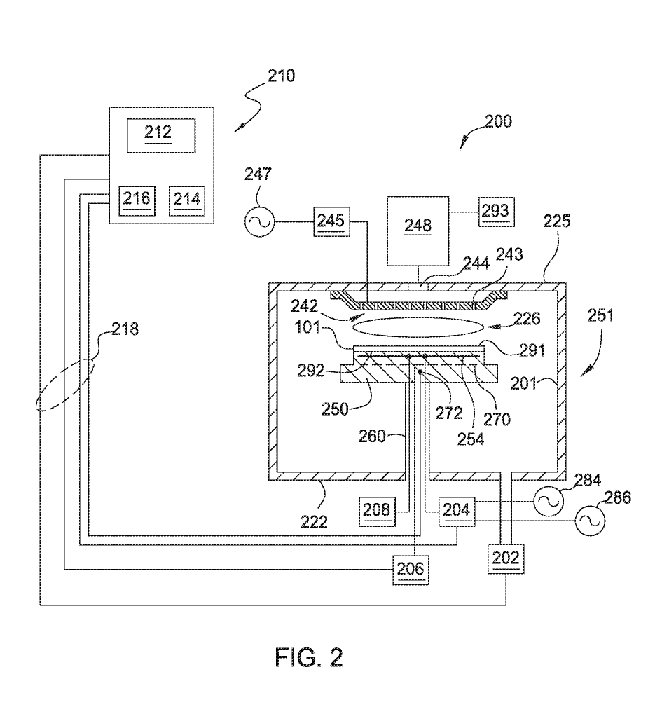

FIG. 2 is a cross sectional view of a processing chamber 200 suitable for performing a plasma deposition process (e.g., a plasma enhanced CVD or a metal organic CVD) that may be utilized as semiconductor interconnection structures for semiconductor devices manufacture. The processing chamber 200 may be a suitably adapted CENTURA®, PRODUCER® SE or PRODUCER® GT or PRODUCER® XP processing system available from Applied Materials, Inc., of Santa Clara, Calif. It is contemplated that other processing systems, including those produced by other manufacturers, may benefit from embodiments described herein.

The processing chamber 200 includes a chamber body 251. The chamber body 251 includes a lid 225, a sidewall 201 and a bottom wall 222 that define an interior volume 226.

A substrate support pedestal 250 is provided in the interior volume 126 of the chamber body 251. The pedestal 250 may be fabricated from aluminum, ceramic, aluminum nitride, and other suitable materials. In one embodiment, the pedestal 250 is fabricated by a ceramic material, such as aluminum nitride, which is a material suitable for use in a high temperature environment, such as a plasma process environment, without causing thermal damage to the pedestal 250. The pedestal 250 may be moved in a vertical direction inside the chamber body 251 using a lift mechanism (not shown).

The pedestal 250 may include an embedded heater element 270 suitable for controlling the temperature of a substrate 101 supported on the pedestal 250. In one embodiment, the pedestal 250 may be resistively heated by applying an electric current from a power supply 206 to the heater element 270. In one embodiment, the heater element 270 may be made of a nickel-chromium wire encapsulated in a nickel-iron-chromium alloy (e.g., INCOLOY®) sheath tube. The electric current supplied from the power supply 206 is regulated by the controller 210 to control the heat generated by the heater element 270, thus maintaining the substrate 101 and the pedestal 250 at a substantially constant temperature during film deposition at any suitable temperature range. In another embodiment, the pedestal may be maintained at room temperature as needed. In yet another embodiment, the pedestal 250 may also include a chiller (not shown) as needed to cool the pedestal 250 at a range lower than room temperature as needed. The supplied electric current may be adjusted to selectively control the temperature of the pedestal 250 between about 20 degrees Celsius to about 700 degrees Celsius.

A temperature sensor 272, such as a thermocouple, may be embedded in the substrate support pedestal 250 to monitor the temperature of the pedestal 250 in a conventional manner. The measured temperature is used by the controller 210 to control the power supplied to the heater element 270 to maintain the substrate at a desired temperature.

The pedestal 250 generally includes a plurality of lift pins (not shown) disposed therethrough that are configured to lift the substrate 101 from the pedestal 250 and facilitate exchange of the substrate 101 with a robot (not shown) in a conventional manner.

The pedestal 250 comprises at least one electrode 292 for retaining the substrate 101 on the pedestal 250. The electrode 292 is driven by a chucking power source 208 to develop an electrostatic force that holds the substrate 101 to the pedestal surface, as is conventionally known. Alternatively, the substrate 101 may be retained to the pedestal 250 by clamping, vacuum or gravity.

In one embodiment, the pedestal 250 is configured as a cathode having the electrode 292 embedded therein coupled to at least one RF bias power source, shown in FIG. 2 as two RF bias power sources 284, 286. Although the example depicted in FIG. 2 shows two RF bias power sources, 284, 286, it is noted that the number of the RF bias power sources may be any number as needed. The RF bias power sources 284, 286 are coupled between the electrode 292 disposed in the pedestal 250 and another electrode, such as a gas distribution plate 242 or lid 225 of the processing chamber 200. The RF bias power source 284, 286 excites and sustains a plasma discharge formed from the gases disposed in the processing region of the processing chamber 200.

In the embodiment depicted in FIG. 2, the dual RF bias power sources 284, 286 are coupled to the electrode 292 disposed in the pedestal 250 through a matching circuit 204. The signal generated by the RF bias power source 284, 286 is delivered through matching circuit 204 to the pedestal 250 through a single feed to ionize the gas mixture provided in the processing chamber 200, thereby providing ion energy necessary for performing a deposition or other plasma enhanced process. The RF bias power sources 284, 286 are generally capable of producing an RF signal having a frequency of from about 50 kHz to about 200 MHz and a power between about 0 Watts and about 5000 Watts.

It is noted that in one example depicted herein, the plasma is only turned on when a cleaning process is performed in the processing chamber 200 as needed.

A vacuum pump 202 is coupled to a port formed in the bottom 222 of the chamber body 251. The vacuum pump 202 is used to maintain a desired gas pressure in the chamber body 251. The vacuum pump 202 also evacuates post-processing gases and by-products of the process from the chamber body 251.

The processing chamber 200 includes one or more gas delivery passages 244 coupled through the lid 225 of the processing chamber 200. The gas delivery passages 244 and the vacuum pump 202 are positioned at opposite ends of the processing chamber 200 to induce laminar flow within the interior volume 226 to minimize particulate contamination.

The gas delivery passage 244 is coupled to the gas panel 293 through a remote plasma source (RPS) 248 to provide a gas mixture into the interior volume 226. In one embodiment, the gas mixture supplied through the gas delivery passage 244 may be further delivered through a gas distribution plate 242 disposed below the gas delivery passage 244. In one example, the gas distribution plate 242 having a plurality of apertures 243 is coupled to the lid 225 of the chamber body 251 above the pedestal 250. The apertures 243 of the gas distribution plate 242 are utilized to introduce process gases from the gas panel 293 into the chamber body 251. The apertures 243 may have different sizes, number, distributions, shape, design, and diameters to facilitate the flow of the various process gases for different process requirements. A plasma is formed from the process gas mixture exiting the gas distribution plate 242 to enhance thermal decomposition of the process gases resulting in the deposition of material on the surface 291 of the substrate 101.

The gas distribution plate 242 and substrate support pedestal 250 may be formed a pair of spaced apart electrodes in the interior volume 226. One or more RF sources 247 provide a bias potential through a matching network 245 to the gas distribution plate 242 to facilitate generation of a plasma between the gas distribution plate 242 and the pedestal 250. Alternatively, the RF sources 247 and matching network 245 may be coupled to the gas distribution plate 242, substrate support pedestal 250, or coupled to both the gas distribution plate 242 and the substrate support pedestal 250, or coupled to an antenna (not shown) disposed exterior to the chamber body 251. In one embodiment, the RF sources 247 may provide between about 10 Watts and about 3000 Watts at a frequency of about 30 kHz to about 13.6 MHz. Alternatively, the RF source 247 may be a microwave generator that provide microwave power to the gas distribution plate 242 that assists generation of the plasma in the interior volume 226.

In one embodiment, the remote plasma source (RPS) 248 may be alternatively coupled to the gas delivery passages 244 to assist in forming a plasma from the gases supplied from the gas panel 293 into the in the interior volume 226. The remote plasma source 248 provides plasma formed from the gas mixture provided by the gas panel 293 to the processing chamber 200.

The controller 210 includes a central processing unit (CPU) 212, a memory 216, and a support circuit 214 utilized to control the process sequence and regulate the gas flows from the gas panel 293. The CPU 212 may be of any form of a general purpose computer processor that may be used in an industrial setting. The software routines can be stored in the memory 216, such as random access memory, read only memory, floppy, or hard disk drive, or other form of digital storage. The support circuit 214 is conventionally coupled to the CPU 212 and may include cache, clock circuits, input/output systems, power supplies, and the like. Bi-directional communications between the controller 210 and the various components of the processing chamber 200 are handled through numerous signal cables collectively referred to as signal buses 218, some of which are illustrated in FIG. 2.

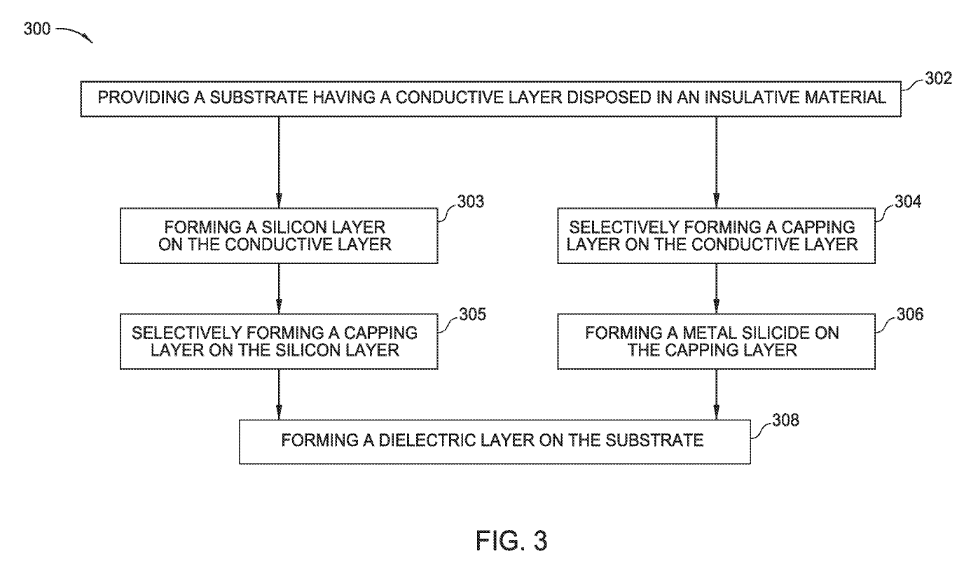

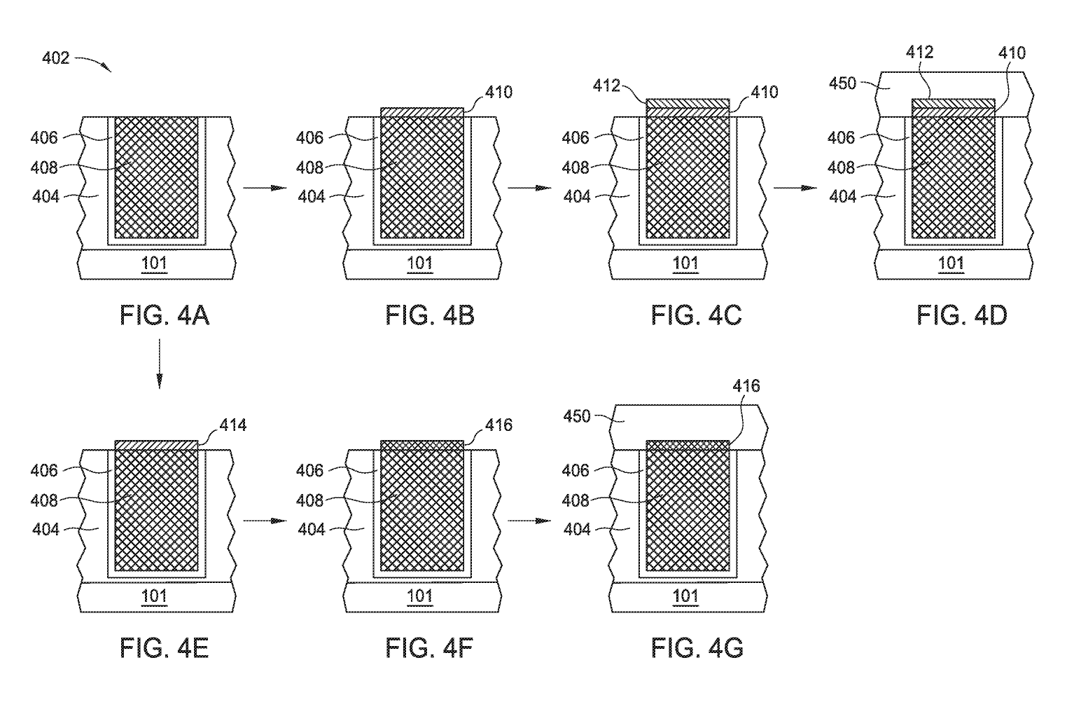

FIG. 3 is a flow diagram of one example of forming a capping protection structure on a metal layer for semiconductor structure. The structure may be any suitable structures formed on a semiconductor substrate, such as interconnection structure with conductive and non-conductive areas, a fin structure, a gate structure, a contact structure, a front-end structure, a back-end structure or any other suitable structures utilized in semiconductor applications. FIGS. 4A-4G are schematic cross-sectional views of a portion of a substrate 101 corresponding to various stages of the process 300. The process 300 may be utilized to a back-end interconnection structure both conductive and non-conductive areas formed on a substrate so as to form desired materials formed on different locations of the back-end interconnection structure. Alternatively, the process 300 may be beneficially utilized to selectively form a capping layer on a metal layer of a substrate without on other types of materials, e.g., insulating material, on the substrate.

The process 300 begins at operation 302 by providing a substrate, such as the substrate 101 as shown in FIG. 4A, into the processing chamber 100 as depicted in FIG. 1 or the processing chamber 200 depicted in FIG. 2. In one embodiment, the substrate 101 may have an interconnection structure 402 formed on the substrate 101. The substrate 101 may have a substantially planar surface, an uneven surface, or a substantially planar surface having a structure formed thereon. The substrate 101 shown in FIG. 4A includes an interconnection structure 402, such as a dual damascene structure, a contact interconnection structure, a passivation structure or the like, formed on the substrate 101. In one embodiment, the substrate 101 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 101 may have various dimensions, such as 200 mm, 300 mm or 450 mm diameter wafers, as well as, rectangular or square panels. Unless otherwise noted, embodiments and examples described herein are conducted on substrates with a 300 mm diameter or a 450 mm diameter.

In one embodiment, the interconnection structure 402 is an interconnection structure utilized in the contact metal or back end semiconductor process. The interconnection structure 402 includes a dielectric bulk insulating layer 404 having at least one metal layer 408, such as copper line, disposed therein laterally bounded by a barrier layer 406 formed in the dielectric bulk insulating 304. In one embodiment, the dielectric bulk insulating layer 404 is a dielectric material having a dielectric constant less than 4.0 (e.g., a low-k material). Examples of suitable materials include carbon-containing silicon oxides (SiOC), such as BLACK DIAMOND® dielectric material available from Applied Materials, Inc., and other low-k polymers, such as polyamides. In the embodiment depicted in FIG. 4A-4G, the dielectric bulk insulating layer 404 is a carbon-containing silicon oxide (SiOC) layer.

The barrier layer 406 is formed to prevent metal diffusion from the conductive metal layer 408 to the nearby surrounding dielectric bulk insulating layer 404. Thus, the barrier layer 406 is selected to have good barrier properties to block ion diffusion therethrough during the subsequent thermal cycles and processes. In one embodiment, the barrier layer 406 is fabricated by a metal containing layer, such as Ru containing materials, TaN, TiN, TaON, TiON, Ti, Ta, Co containing materials, Ru containing materials, Mn containing materials and the like. In the embodiment depicted herein, the barrier layer 406 is a Ru layer or a Ru alloy.

The metal layer 408 formed in the dielectric bulk insulating layer 404 is a conductive material, such as copper, aluminum, tungsten, cobalt, nickel, or other suitable materials. In the embodiment depicted in FIGS. 4A-4G, the metal layer 408 is a copper layer.

At operation 304, a deposition process is performed to form a silicon layer 410 on the metal layer 408, as shown in FIG. 4B. The deposition process may be an ALD process performed at the ALD processing chamber 100 depicted in FIG. 1, or a CVD process performed at the CVD processing chamber 200 depicted in FIG. 2. In one embodiment, the silicon layer 410 may be formed by flowing a silicon containing gas onto the substrate surface, to form the silicon layer 410 on the metal layer 408. Although in the example depicted in FIG. 4B shows that the silicon layer 410 is selectively formed on the metal layer 408, it is noted that the silicon layer 410 may be globally formed across the substrate surface.

In one embodiment, suitable examples of the silicon containing gas supplied to form the silicon layer 410 include silane (SiH₄), disilane (Si₂H₆), silicon tetrafluoride (SiF₄), tetraethyl orthosilicate (TEOS), silicon tetrachloride (SiCl₄), dichlorosilane (SiH₂Cl₂), and combinations thereof. In one example, the silicon-based gas is silane (SiH₄). Other carrier gas, and/or dilution gas, such as Ar, He, N₂, N₂O, NO₂, NH₃ may also be supplied with the silicon containing gas.

During the silicon layer formation process, several process parameters may be regulated to control the process. In one exemplary embodiment, a process pressure is regulated between about 10 mTorr to about 5000 mTorr, such as between about 400 mTorr and about 2000 mTorr. A RF source power or a RF bias power may or may not be supplied with the silicon containing gas. In one example, the RF source and/or bias power is not applied during the silicon layer formation process at operation 303. A substrate temperature is maintained between about 25 degrees Celsius to about 450 degrees Celsius. In one embodiment, the substrate 101 is subjected to the silicon containing gas flow for between about 5 seconds to about 5 minutes, depending on the operating temperature, pressure and flow rate of the gas. The silicon layer 410 (or metal silicide) may have a thickness between about 5 Å and about 15 Å, such as about 10 Å.

As the silicon layer 410 is formed on and in direct contact with the metal layer 408, the silicon layer 410 may include the metal elements from the metal layer 408 attached thereto, due to the surface absorption (e.g., interface reaction), forming a metal silicide layer. In the example wherein the metal layer 408 is a copper layer, the silicon layer 410 may be a copper containing silicon layer, such as a copper silicide layer, when the silicon elements from the silicon layer 410 once in contact with the copper elements. It is noted that based on the types of the metal layer 408 formed on the substrate 101, the silicon layer 410 formed thereon may react with the metal elements from the metal layer 408 to form different types of the metal silicide as needed.

In some examples, a thermal annealing process or a thermal treating process may or may not be performed to enhance the surface interface between the silicon elements and the copper elements to form a relatively strong interface bonding of the copper silicide layer as needed.

At operation 305, after the silicon layer 410 is formed, a capping layer 412 may be then selectively formed on the silicon layer 410 (or the metal silicide layer), as shown in FIG. 4C. The capping layer 412 may be selectively formed on the silicon layer 410 (or the metal silicide) formed on the metal layer 408. The capping layer 412 may also be a metal containing layer formed by an ALD process performed at the ALD processing chamber 100 depicted in FIG. 1, or a CVD process performed at the CVD processing chamber 200 depicted in FIG. 2.

In one example, the capping layer 412 may seal the silicon layer 410 to reduce likelihood of the metal layer 408 being out-diffused in the following processing cycles, thus reducing the likelihood of electron migration or other device failure. The capping layer 412 is selected to be fabricated from a material having a relatively good interface blocking property to prevent the metal elements from the metal layer 408 (e.g., copper elements) from diffusing outward to the nearby insulating materials. In one embodiment, the capping layer 412 may be cobalt containing materials, tungsten containing materials, nickel containing materials, aluminum containing materials, ruthenium containing materials, or manganese containing materials. In one embodiment, the capping layer 412 is a cobalt containing layer. It is noted that the capping layer 412 may only be selectively formed on the silicon layer 410 (or the metal silicide layer). Alternatively, the capping layer 412 may be formed in the entire surface of the substrate 101, including above the metal layer 408 and the dielectric bulk insulating layer 404.

In one example, the capping layer 412 is a Co layer or a Co alloy. In one example, the capping layer 412 is formed by a cyclical layer deposition (CLD), atomic layer deposition (ALD), chemical vapor deposition (CVD), or the like. The capping layer 412 is formed by supplying a deposition precursor gas mixture including a cobalt precursor simultaneously with, sequentially with, or alternatively without a reducing gas mixture (or called reagent), such as a hydrogen gas (H₂) or a NH₃ gas, into the metal deposition processing chamber, such as the processing chambers 100 or 200 in FIGS. 1 and 2, during a thermal CVD process, a pulsed-CVD process, a PE-CVD process, a pulsed PE-CVD process, or a thermal ALD process. Additionally, the deposition precursor gas mixture may also include purge gas mixture to concurrently supply into the processing chamber for processing. In another embodiment, the capping layer 412 may be formed or deposited by sequentially repetitively introducing a pulse of deposition precursor gas mixture, such as a cobalt precursor, and a pulse of a reducing gas mixture, such as a hydrogen gas (H₂) or a NH₃ gas, during a thermal ALD process or a pulsed PE-CVD process.

Suitable cobalt precursors may include, but not limited to, cobalt carbonyl complexes, cobalt amidinates compounds, cobaltocene compounds, cobalt dienyl complexes, cobalt nitrosyl complexes, derivatives thereof, complexes thereof, plasmas thereof, or combinations thereof. In one embodiment, examples of the cobalt precursors that may be used herein include dicobalt hexacarbonyl butylacetylene (CCTBA, (CO)₆Co₂(HC≡C^{t}Bu)), dicobalt hexacarbonyl methylbutylacetylene ((CO)₆Co₂(MeC≡C^{t}Bu)), dicobalt hexacarbonyl phenylacetylene ((CO)₆Co₂(HC≡CPh)), hexacarbonyl methylphenylacetylene ((CO)₆Co₂(MeC≡CPh)), dicobalt hexacarbonyl methylacetylene ((CO)₆Co₂(HC≡CMe)), dicobalt hexacarbonyl dimethylacetylene ((CO)₆Co₂(MeC≡CMe)), derivatives thereof, complexes thereof, plasmas thereof, or combinations thereof. Other exemplary cobalt carbonyl complexes include cyclopentadienyl cobalt bis(carbonyl) (CpCo(CO)₂), tricarbonyl allyl cobalt ((CO)₃Co(CH₂CH═CH₂)), derivatives thereof, complexes thereof, plasmas thereof, or combinations thereof. In one particular example of the cobalt precursors used herein is dicobalt hexacarbonyl butylacetylene (CCTBA, (CO)₆Co₂(HC≡C^{t}Bu)). It is noted that the dicobalt hexacarbonyl butylacetylene (CCTBA, (CO)₆Co₂(HC≡C^{t}Bu)) precursor may be supplied into the metal deposition processing chamber 150 with a carrier gas, such as a Ar gas.

Examples of the alternative reagents (i.e., reducing agents used with cobalt precursors for forming the cobalt materials during the deposition process as described herein may include hydrogen (e.g., H₂ or atomic-H), nitrogen (e.g., N₂ or atomic-N), ammonia (NH₃), hydrazine (N₂H₄), a hydrogen and ammonia mixture (H₂/NH₃), borane (BH₃), diborane (B₂H₆), triethylborane (Et₃B), silane (SiH₄), disilane (Si₂H₆), trisilane (Si₃H₈), tetrasilane (Si₄H₁₀), methyl silane (SiCH₆), dimethylsilane (SiC₂H₈), phosphine (PH₃), derivatives thereof, plasmas thereof, or combinations thereof. In one particular example of the reagents or reducing agents used herein is ammonia (NH₃).

In one example, the capping layer 412 may have a thickness of about above 15 Å, such as between 18 Å and 35 Å, for example about 20 Å.

As the material of the capping layer 412 (e.g., a Co layer or a Co alloy) is selected to be different from the material of the metal layer 408 (e.g., a Cu layer or a Cu alloy), thus, the metal silicide layer (e.g., Cu silicide) sourced from the silicon layer 410 may have a metal element (e.g., Cu or Cu alloy) different from the metal element (e.g., Co or Co alloy) from the capping layer 412.

At operation 308, after the capping layer 412 is formed, a dielectric layer 450 is then formed thereon, as shown in FIG. 4D. The dielectric layer 450 may be a dielectric layer with low dielectric constant, such as low dielectric constant less than 4.0 (e.g., a low-k material). In one embodiment, the dielectric layer 450 may be a carbon-containing silicon oxides (SiOC), such as BLACK DIAMOND® or BLOK® dielectric material available from Applied Materials, Inc. Alternatively, the dielectric layer 450 may be any suitable dielectric materials, polymer materials, such as polyamides, SOG, or the like. In one embodiment, the dielectric layer 450 may be a SiOC layer with a thickness between about 10 Å and about 200 Å.

Alternatively, in another embodiment, rather than forming the silicon layer 410 first on the metal layer 408, in operation 304, the capping layer 414 may be formed on the metal layer 408 to be in direct contact with the metal layer 408, as shown in FIG. 4E. The capping layer 414 is similar to the capping layer 412 as described above at operation 305. In operation 306, after the capping layer 414 is formed, a metal silicide layer 416 is formed on the capping layer 414, as shown in FIG. 4F. Similar to the silicon layer formation at operation 303, the metal silicide layer 416 may be formed by forming a silicon layer first on the capping layer 414 and then reacts with the metal elements from the capping layer 414 to form the metal silicide layer 416. In this example, as the capping layer 414 is a Co layer or a Co alloy, the metal silicide layer 416 is a Co silicide layer. The silicon layer formed on the capping layer 414 to form the metal silicide layer 416 may be the same or similar to the silicon layer 410 formed at operation 303. The metal silicide layer 416 has a thickness of between about 5 Å and about 15 Å, such as about 10 Å.

As the material of the capping layer 414 (e.g., a Co layer or a Co alloy) is selected to be different from the material of the metal layer 408 (e.g., a Cu layer or a Cu alloy), thus, the metal silicide layer 416 (e.g., Co silicide) may have a metal element (e.g., Co or Co alloy) different from the metal element (e.g., Cu or Cu alloy) from the metal layer 408.

Similarly, after the metal silicide layer 416 is formed, the dielectric layer 450 is then formed thereon, as shown in FIG. 4G, similar to the operation 308 described above. The dielectric layer 450 may be a dielectric layer with low dielectric constant, such as low dielectric constant less than 4.0 (e.g., a low-k material). In one embodiment, the dielectric layer 450 may be a carbon-containing silicon oxides (SiOC), such as BLACK DIAMOND® or BLOK® dielectric material available from Applied Materials, Inc. Alternatively, the dielectric layer 450 may be any suitable dielectric materials, polymer materials, such as polyamides, SOG, or the like. In one embodiment, the dielectric layer 450 may be a SiOC layer with a thickness between about 10 Å and about 200 Å.

It is noted that the silicon layer 410, the capping layer 412 and the dielectric layer 450 may be may be in-situ deposited and completed in one processing chamber, or ex-situ deposited in different processing chambers of a multi-chamber processing system as needed. Similarly, the capping layer 414, the metal silicide layer 416 and the dielectric layer 450 may be may be in-situ deposited and completed in one processing chamber, or ex-situ deposited in different. The capping layer 412, 414, along with the silicon layer 410 or the metal silicide layer 416 provides a good interface control as well as good blocking/barrier property to enhance electrical device performance of the device structure.

Thus, a method and an apparatus for forming a capping protection for a metal line in an interconnection structure are provided. The capping layer along with a metal silicide layer formed on the metal line may efficiently protect the metal line from out-diffusion, thereby eliminating likelihood of electron migration or current leakage, maintaining a good interface control. By utilizing a proper capping protection formed on a metal line, the metal line may be controlled with electrical degradation, thereby increasing the device performance.

While the foregoing is directed to embodiments of the present invention, other and further embodiments of the invention can be devised without departing from the basic scope thereof, and the scope thereof is determined by the claims that follow.

What is claimed is:

1. A method for forming capping protection on a metal line in an interconnection structure for semiconductor devices, comprising:
selectively forming a metal silicide layer on a metal line bounded by a dielectric bulk insulating layer in a back end interconnection structure formed on a substrate in a processing chamber; and
forming a dielectric layer on the metal silicide layer.

2. The method of claim 1, wherein the metal silicide layer is a copper silicide or a cobalt silicide.

3. The method of claim 1, wherein the metal line comprises a copper layer or a copper alloy.

4. The method of claim 1, wherein selectively forming the metal silicide layer further comprises:
supplying a silicon containing gas to the substrate;
forming a silicon layer on and in direct contact with the metal line; and
forming a capping layer on the silicon layer.

5. The method of claim 4, wherein the capping layer is formed by supplying a cobalt containing precursor to the substrate.

6. The method of claim 4, wherein the metal silicide layer is a copper silicide layer.

7. The method of claim 4, wherein the capping layer is a Co layer or a Co alloy.

8. The method of claim 4, wherein the silicon containing gas is at least one of silane (SiH₄), disilane (Si₂H₆), silicon tetrafluoride (SiF₄), tetraethyl orthosilicate (TEOS), silicon tetrachloride (SiCl₄) and dichlorosilane (SiH₂Cl₂).

9. The method of claim 1, wherein selectively forming the metal silicide layer further comprises:
forming a capping layer on in direct contact with the metal line; and
forming the metal silicide layer on the capping layer.

10. The method of claim 9, wherein the metal silicide layer is a cobalt silicide layer.

11. The method of claim 9, wherein the capping layer is a cobalt layer or a cobalt alloy.

12. The method of claim 1, wherein the metal silicide layer has a thickness of between about 5 Å and about 15 Å.

13. The method of claim 1, wherein the dielectric capping layer is a low k material having a dielectric constant less than 4.

14. A semiconductor back end interconnection structure, comprising:
a copper metal line bounded by a dielectric bulk insulating layer in a back end interconnection structure formed on a substrate;
a metal silicide layer disposed on the copper metal layer; and
a dielectric layer disposed on the metal silicide layer.

15. The semiconductor back end interconnection structure of claim 14, wherein the metal silicide layer is a copper silicide or a cobalt silicide.

16. The semiconductor back end interconnection structure of claim 14, wherein the metal silicide layer has a metal element different from a metal element from the copper metal line.

17. The semiconductor back end interconnection structure of claim 14, further comprising:
a capping layer formed between the metal silicide layer and the dielectric layer.

18. The semiconductor back end interconnection structure of claim 14, the capping layer is a Co layer or a Co alloy.

19. A method for forming capping protection on a metal line in an interconnection structure for semiconductor devices, comprising:
supplying a silicon containing gas to a metal line bounded by a dielectric bulk insulating layer in a back end interconnection structure formed on a substrate;
forming a metal silicide layer on the metal layer;
supplying a cobalt containing gas to the metal line formed on the substrate to form a capping layer on the metal silicide layer; and
forming a dielectric layer on the capping layer.

20. The method of claim 19, wherein the capping layer is a Co layer or a Co alloy.
